(19) United States
(12) Patent Application Publication
(10) Pub. No.: US 2025/0231836 A1
(43) Pub. Date: Jul. 17, 2025

(54) DOUBLE DEVICE DATA CORRECTION FOR REDUNDANT- ARRAY-OF-INDEPENDENT-DISKS-BASED SYSTEMS

(71) Applicant: Micron Technology, Inc., Boise, ID (US)

(72) Inventor: Marco SFORZIN, Cernusco Sul Naviglio (IT)

(21) Appl. No.: 18/985,888

(22) Filed: Dec. 18, 2024

Related U.S. Application Data
(60) Provisional application No. 63/621,787, filed on Jan. 17, 2024.

(51) Int. Cl. G06F 11/10

(52) U.S. Cl. CPC G06F 11/1076; G06F 11/1016

(57) ABSTRACT

In some implementations, a memory system may receive a first read command associated with a first memory stripe that includes multiple data storage elements and that is associated with one or more error correction elements. The memory system may perform a first read procedure based on receiving the first read command. The memory system may identify a first read error associated with a first data storage element and may perform a first read error recovery procedure using the one or more error correction elements. The memory system may receive a second read command associated with the first memory stripe. The memory system may perform a second read procedure based on receiving the second read command. The memory system may identify a second read error associated with a second data storage element and may perform a second read error recovery procedure using the one or more error correction elements.

### CROSS-REFERENCE TO RELATED APPLICATION

This Patent application claims priority to U.S. Provisional Patent Application No. 63/621,787, filed on Jan. 17, 2024, entitled “DOUBLE DEVICE DATA CORRECTION FOR REDUNDANT-ARRAY-OF-INDEPENDENT-DISKS-BASED SYSTEMS,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to double device data correction for redundant-array-of-independent-disks-based systems.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. In some examples, a memory device may be associated with a compute express link (CXL). For example, the memory device may be a CXL compliant memory device and/or may include a CXL interface.

### BRIEF DESCRIPTION OF THE DRAWINGS

FIG. 1 is a diagram illustrating an example system capable of performing double device data correction for redundant array of independent disks (RAID)-based systems, among other examples.

FIG. 2 is a diagram of an example associated with a RAID read recovery procedure.

FIGS. 3A-3B are diagrams of examples associated with double device data correction for RAID-based systems.

FIG. 4 is a flowchart of an example method associated with double device data correction for RAID-based systems.

FIG. 5 is a flowchart of another example method associated with double device data correction for RAID-based systems.

### DETAILED DESCRIPTION

A memory system may implement a read error recovery procedure for correcting read errors associated with a memory, such as a read error recovery procedure associated with a redundant array of independent disks (RAID) operation or a similar operation. For some RAID operations, sometimes referred to as locked RAID (LRAID) operations, the memory system may stripe host data across multiple elements, dies, and/or memory locations, sometimes referred to collectively as a memory stripe. The memory stripe may include multiple data storage elements (e.g., multiple dies) for storing host data, and an error correction element (e.g., an error correction die, sometimes referred to herein as a parity die) for storing parity bits and/or for use during a read error recovery procedure. In such examples, each data storage element may include a respective set of cyclic redundancy check (CRC) bits stored on extra space associated with the data storage elements (e.g., space of the data storage element that is not used for storing host data), and the error correction element may include parity bits (sometimes referred to as RAID parity bits and/or single parity check (SPC) code) associated with the data stored in the multiple data storage elements. For example, the parity bits may be derived using an exclusive or (XOR) operation associated with the data bits stored on the data storage elements. In this way, the set of CRC bits at each data storage element may be used to detect errors associated with the corresponding data storage element, and the parity bits may be used to correct the errors associated with a data storage element for which an error is detected. More particularly, the memory system may use a set of CRC bits to identify that a certain data storage element has failed, and the memory system may recover the lost data by using the data of the remaining data storage elements and the parity bits (e.g., by adding, in a bitwise fashion, the data of the remaining data storage elements to the parity bits), such as by using a multi-tentative approach to identify the error position and/or correct the error.

In this way, certain read error recovery procedures (e.g., RAID procedures or LRAID procedures, among other examples) are effective only if a single data storage element (e.g., one data die) fails and/or contains errors. This is because, in order to correct errors for a given bit location in a given data storage element, the memory system may need to use uncorrupted data bits from the corresponding bit location of each of the remaining data storage elements of the memory stripe as well as the uncorrupted parity bit from the corresponding bit location of the data correction element. Accordingly, such error correction procedures may become ineffective if more than one data storage element of a memory stripe includes errors and/or fails (e.g., when two or more data dies associated with a memory stripe fails). This may result in unreliable memory systems, unrecoverable host data, read/write errors, and high power, computing, and storage consumption for moving host data, rewriting host data, and/or recovering host data.

Some implementations described herein enable double device data correction for certain memory systems, such as the RAID-based memory systems described above and/or memory systems that stripe data across multiple memory elements and/or dies. In some implementations, a memory system may utilize a memory stripe that includes two error correction elements (e.g., two parity dies), including a first error correction element used as a parity die and a second error correction element used as a spare element to replace a failed data storage element. In this way, if a data storage element contains many errors (e.g., as detected via a respective CRC check), the memory system may recover the lost data using the parity data contained at the first error correction element and the remaining data storage elements. Moreover, the memory device may use the second error correction element as a spare element to replace the failed data storage element, and thus may write the recovered data to the second error correction element and/or update the parity bits on the first error correction element to reflect the new payload (e.g., the data of the remaining data storage elements plus the data of the second error correction element). In this way, if another data storage element fails (e.g., as detected via a respective CRC check), the memory system may recover the lost data using the updated parity data contained at the first error correction element, the data contained at the remaining data storage elements, and the data contained at the second error correction element, thereby enabling double device data correction at the memory system, resulting in increased reliability of the memory system, reduced data loss and/or read/write errors, and reduced power, computing, and storage consumption otherwise required to move host data, rewrite host data, and/or recover host data.

In some other implementations, a memory system may associate multiple memory stripes (e.g., two memory stripes) with each other, with each memory stripe including respective multiple data storage elements and a respective error correction element. In such implementations, the error correction element at one of the memory stripes may include a set of parity bits common to both memory stripes (e.g., derived by using an XOR operation associated with the data bits stored on the data storage elements of both memory stripes). In this way, if a data storage element of a first memory stripe fails, the memory system may use the error correction element of the first memory stripe as a spare element to replace the failed data storage element, and may later use the set of parity bits common to both memory stripes (e.g., stored at the error correction element of a second memory stripe) to correct additional errors at the first memory stripe. In this way, if another data storage element of the first memory stripe fails (e.g., as detected via a respective CRC check), the memory system may recover the lost data using the parity data contained in the error correction element of the second memory stripe, thereby enabling double device data correction at the memory system. This may result in increased reliability of the memory system, reduced data loss and/or read/write errors, and reduced power, computing, and storage consumption otherwise required to move host data, rewrite host data, and/or recover host data.

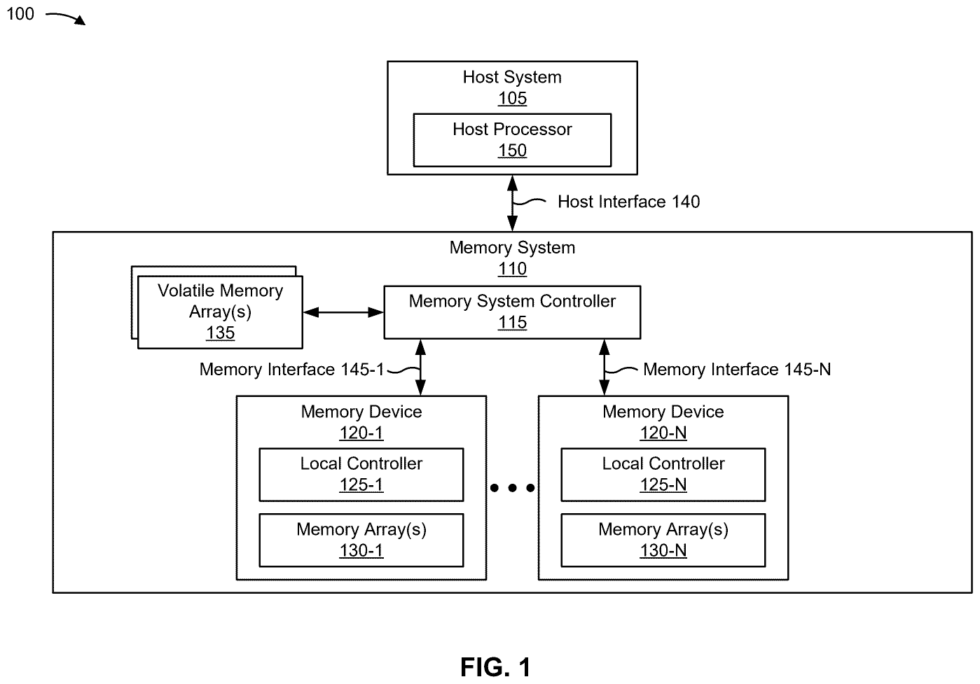

FIG. 1 is a diagram illustrating an example system 100 capable of performing double device data correction for RAID-based systems, among other examples. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device 120 may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

In some examples, the memory system 110 may be a compute express link (CXL) compliant memory system. For example, the memory system 110 may include a PCIe/CXL interface (e.g., the host interface 140 may be associated with a PCIe/CXL interface). CXL is a high-speed CPU-to-device and CPU-to-memory interconnect designed to accelerate next-generation performance. CXL technology maintains memory coherency between the CPU memory space and memory on attached devices, which allows resource sharing for higher performance, reduced software stack complexity, and lower overall system cost. CXL is designed to be an industry open standard interface for high-speed communications. CXL technology is built on the PCIe infrastructure, leveraging PCIe physical and electrical interfaces to provide an advanced protocol in areas such as input/output (I/O) protocol, memory protocol, and coherency interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller.

Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to perform a first read procedure associated with a first memory stripe, wherein the first memory stripe includes multiple data storage elements, and wherein the first memory stripe is associated with one or more error correction elements; identify a first read error associated with the first read procedure, wherein the first read error is associated with a first data storage element, of the multiple data storage elements; perform a first read error recovery procedure using the one or more error correction elements; perform a second read procedure associated with the first memory stripe; identify a second read error associated with the second read procedure, wherein the second read error is associated with a second data storage element, of the multiple data storage elements, that is a different data storage element than the first data storage element; and perform a second read error recovery procedure using the one or more error correction elements.

In some implementations, one or more systems, devices, apparatuses, components, and/or controllers of FIG. 1 may be configured to receive a first read command associated with a first memory stripe, wherein the first memory stripe includes multiple data storage elements, and wherein the first memory stripe is associated with one or more error correction elements; perform a first read procedure based on receiving the first read command; identify a first read error associated with the first read procedure, wherein the first read error is associated with a first data storage element, of the multiple data storage elements; perform a first read error recovery procedure using the one or more error correction elements; receive a second read command associated with the first memory stripe; perform a second read procedure based on receiving the second read command; identify a second read error associated with the second read procedure, wherein the second read error is associated with a second data storage element, of the multiple data storage elements, that is a different data storage element than the first data storage element; and perform a second read error recovery procedure using the one or more error correction elements.

In some implementations, one or more systems, devices, apparatuses, components, and/or controllers of FIG. 1 may be configured to perform a first read procedure associated with a first memory stripe, wherein the first memory stripe includes multiple data storage elements, and wherein the first memory stripe is associated with one or more error correction elements; identify a first read error associated with the first read procedure, wherein the first read error is associated with a first data storage element, of the multiple data storage elements; perform a first read error recovery procedure using the one or more error correction elements; perform a second read procedure associated with the first memory stripe; identify a second read error associated with the second read procedure, wherein the second read error is associated with a second data storage element, of the multiple data storage elements, that is a different data storage element than the first data storage element; and perform a second read error recovery procedure using the one or more error correction elements.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

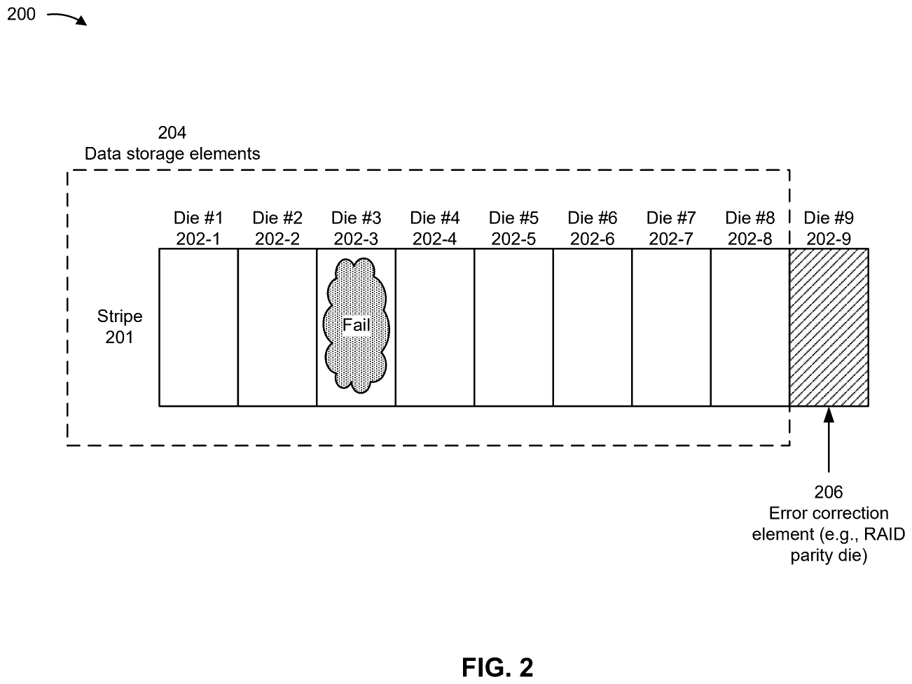

FIG. 2 is a diagram of an example 200 associated with a RAID read recovery procedure. The operations described in connection with FIG. 2 may be performed by the memory system 110 and/or one or more components of the memory system 110, such as the memory system controller 115, one or more memory devices 120, and/or one or more local controllers 125.

In some examples, a memory system (e.g., memory system 110) may be configured to stripe host data across multiple memory locations, elements, and/or dies, such as for purposes of implementing a RAID operation (e.g., an LRAID operation). In that regard, the memory system may be referred to as a RAID-based system. As shown in FIG. 2, in some RAID-based systems (e.g., in some LRAID-based systems), a memory system may store host data using a memory stripe 201, which may include multiple elements 202 (e.g., multiple arrays, dies, disks, or the like), shown in FIG. 2 as a first element 202-1 through a ninth element 202-9. In that regard, the memory stripe 201 may be a logical group of memory elements (e.g., elements 202) forming single striped operations (e.g., write operations, read operations, or erase operations, among other examples). In some examples, utilizing the memory stripe 201 that includes multiple elements 202 may enable a memory system to utilize distributed parity and/or redundancy techniques such that, if one element 202 of the memory stripe 201 fails, the memory system may restore host data using the other elements 202 in the memory stripe 201.

More particularly, as indicated by reference number 204, the memory stripe 201 may be associated with multiple data storage elements, such as the first element 2021-1 through the eighth element 202-8 in the example shown in FIG. 2, but which may include fewer or additional elements in some other examples. As indicated by reference number 206, the memory stripe 201 may also be associated with an error correction element, such as the ninth element 202-9 in the example shown in FIG. 2. In some examples, the data storage elements may be used to store host data, and the error correction element may be used to stored parity bits used for error correction of the host data. For example, in RAID-based systems, the data storage elements may be associated with a parity check payload, and the error correction element may be used to store parity bits associated with the parity check payload (e.g., RAID parity bits). In some cases, the parity bits may be derived from the party check payload, such as by performing an XOR operation associated with the data bits stored on the data storage elements. For example, for a given bit location in the error correction element, a value of the error correction bit (e.g., parity bit) may be derived by performing an XOR operation using the data bits located at the given bit location of each data storage element.

In such examples, the set of parity bits included at the error correction element may be used to recover any data that is lost on a given data storage element, such as due to a failed die, disk, array, or the like. For example, each data storage element (e.g., the first element 202-1 through the eighth element 202-8) may include a respective set of CRC bits, such as a set of CRC bits stored in space of the data storage element that is not used for storing host data. In this way, if an error occurs at a data storage element, such as if the third data storage element 202-3 fails (as shown in FIG. 2 as “Fail”), the memory system may detect the error using a CRC check associated with the third data storage element 202-3. Once detected, the memory system may use the remaining data storage elements (e.g., the first element 202-1, the second element 202-2, and the fourth element 202-4 through the eighth element 202-8), as well as the error correction element (e.g., the ninth element 202-9) to recover the lost data associated with the failed third element 202-3. For example, the memory system may derive the lost data by adding (e.g., in a bitwise fashion using an XOR operation) host data bits stored at the remaining data storage elements (e.g., the first element 202-1, the second element 202-2, and the fourth element 202-4 through the eighth element 202-8) to the parity bits stored at the error correction element (e.g., the ninth element 202-9). Accordingly, the set of CRC bits at each data storage element may be used to detect errors associated with the corresponding data storage element, and the parity bits may be used to correct the errors associated with a data storage element for which an error is detected.

In this way, certain read error recovery procedures (e.g., RAID procedures or LRAID procedures, among other examples) may be effective only if a single data storage element 202 (e.g., a single data die) fails and/or contains errors. This is because, in order to correct errors for a given bit location in a given data storage element, the memory system may need to use uncorrupted data bits from the corresponding bit location of each of the remaining data storage elements as well as the uncorrupted parity bit from the corresponding bit location of the data correction element. Accordingly, such error correction procedures may become ineffective if more than one data storage element of the memory stripe 201 includes multiple errors and/or fails (e.g., when two or more elements 202 associated with the memory stripe 201 fail).

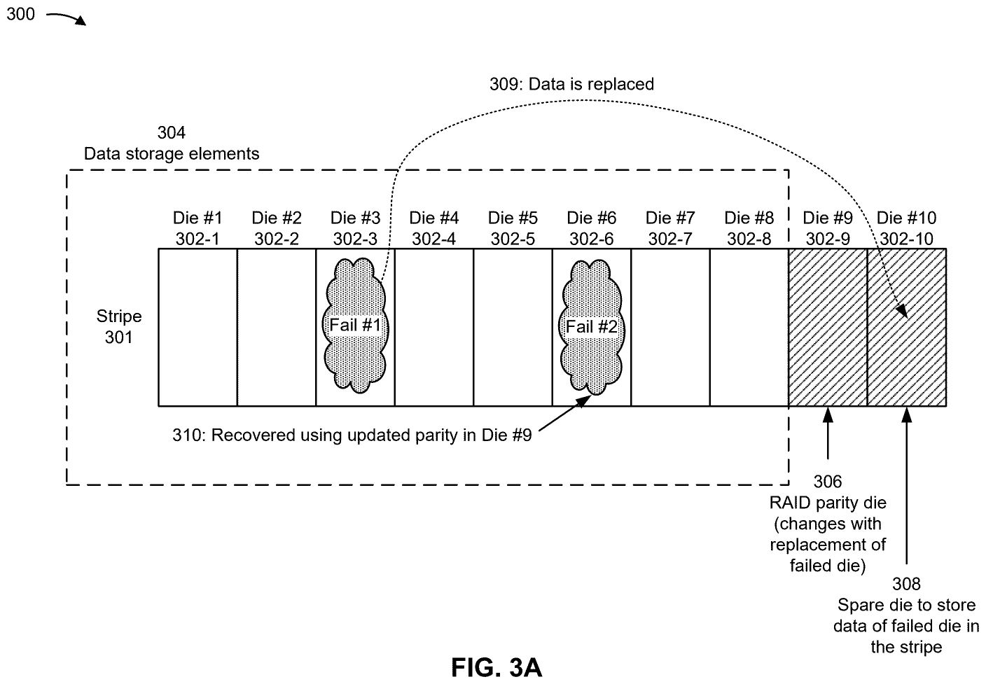

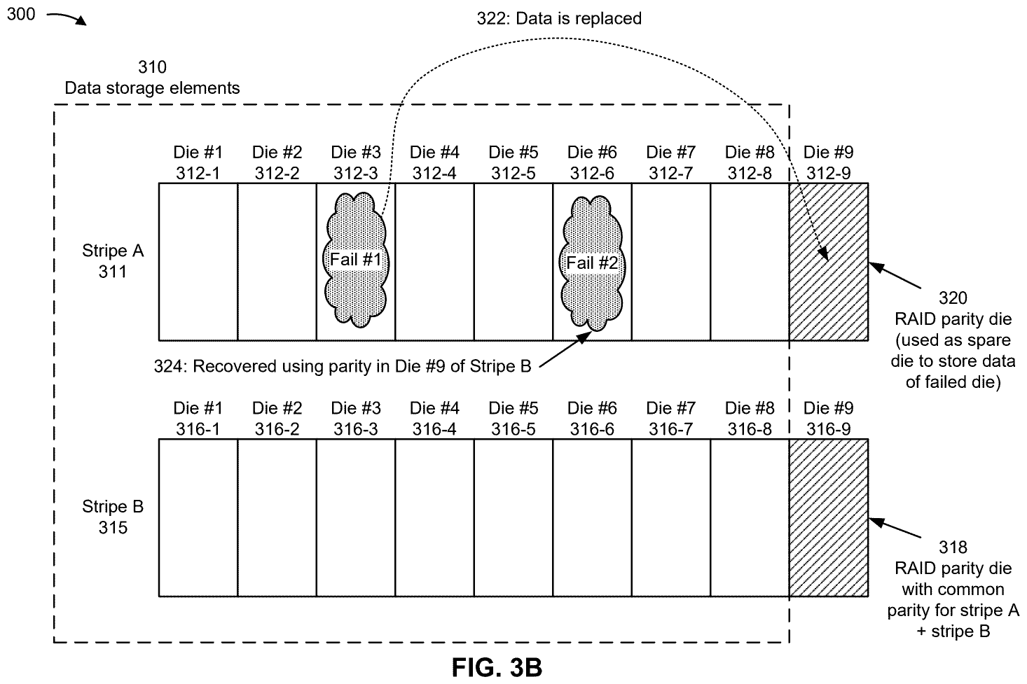

Accordingly to some implementations, a memory system may be capable of performing double device data correction for RAID-based systems, which refers to recovering data for more than one data storage element (e.g., more than one data die) of a memory stripe associated with a RAID operation (e.g., an LRAID operation, among other examples). Implementations associated with double device data correction for RAID-based systems are described in detail below in connection with FIGS. 3A-5.

As indicated above, FIG. 2 is provided as an example. Other examples may differ from what is described with regard to FIG. 2.

FIGS. 3A-3B are diagrams of examples associated with double device data correction for RAID-based systems. That is, FIGS. 3A-3B are diagrams of examples associated with recovering data for more than one failed data storage element (e.g., more than one failed data die) of a memory stripe. The operations described in connection with FIGS. 3A-3B may be performed by the memory system 110 and/or one or more components of the memory system 110, such as the memory system controller 115, one or more memory devices 120, and/or one or more local controllers 125.

In some examples, and in a similar manner as described above in connection with example 200, a memory system (e.g., memory system 110) may be configured to stripe host data across multiple memory locations, elements, and/or dies, such as for purposes of implementing a RAID operation (e.g., an LRAID operation). In that regard, the memory system may be referred to as a RAID-based system. As shown in FIG. 3A, and as indicated by reference number 300, in some RAID-based systems (e.g., in some LRAID-based systems), a memory system may store host data using a memory stripe 301, which may include multiple elements 302 (e.g., multiple arrays, dies, disks, or the like), shown in FIG. 3A as a first element 202-1 through a tenth element 202-10 (labeled in FIG. 3A as Die #1 through Die #10 for case of discussion). In that regard, the memory stripe 301 may be a logical group of memory elements (e.g., elements 302) forming single striped operations (e.g., write operations, read operations, or erase operations, among other examples). In some implementations, utilizing the memory stripe 301 that includes multiple elements 302 may enable a memory system to utilize distributed parity and/or redundancy techniques such that, if one element 302 of the memory stripe 301 fails, the memory system may restore host data using the other elements 302 in the memory stripe 301. Moreover, in some implementations, the memory stripe 301 may be associated with multiple error correction elements (e.g., a ninth element 302-9 and the tenth element 302-10, indicated using cross-hatching), which may enable the memory system to correct errors on multiple data storage elements (e.g., multiple data dies) associated with the memory stripe 301.

More particularly, as indicated by reference number 304, the memory stripe 301 may be associated with multiple data storage elements, such as the first element 302-1 through an eighth element 302-8 in the example shown in FIG. 2, but which may include fewer or additional elements in some other examples, and two error correction elements, such as the ninth element 302-9 and the tenth element 302-10 in the example shown in FIG. 3A (indicated using cross-hatching). In some examples, the data storage elements may be used to store host data, and the error correction elements may be used to store parity bits used for error correction of the host data, among other examples. For example, in RAID-based systems, the data storage elements may be associated with a parity check payload, and one or both of the error correction elements may be used to store parity bits associated with the parity check payload. For example, in the example shown in FIG. 3B, and as indicated by reference number 306, the ninth element 302-9 may be used to store parity bits associated with the parity check payload, and thus may, in some implementations, be referred to as a RAID parity die. As described above in connection with FIG. 2, the parity bits may be derived from the party check payload, such as by performing an XOR operation associated with the data bits stored on the data storage elements.

In some implementations, as indicated by reference number 308, one of the error correction elements (e.g., the tenth element 202-10 in the example shown in FIG. 3B) may be used to store data associated with a failed data storage element. Put another way, the tenth element 302-10 may be used as a spare element (e.g., a spare die) to store data from a failed data storage element in the memory stripe 301. Thus, when performing a read error recovery procedure or a similar procedure, the first error correction element (e.g., the ninth element 302-9) may be used to retrieve an error correction parity (e.g., RAID parity), in a similar manner as the error correction element described above in connection with FIG. 2 (e.g., the ninth element 202-9), and the second error correction element (e.g., the tenth element 302-10) may be used as a spare element to store data of a first failed element in the memory stripe 301.

More particularly, the set of parity bits included at the first error correction element (e.g., the ninth element 302-9) may be used to recover any data that is lost on a given data storage element, such as due to a failed die, disk, array, or the like. For example, in a similar manner as described above in connection with FIG. 2, each data storage element (e.g., the first element 302-1 through the eighth element 302-8) may include a respective set of CRC bits, such as a set of CRC bits stored in space of the data storage element that is not used for storing host data. In this way, if a first error occurs at a data storage element, such as if the third element 302-3 fails in the example shown in FIG. 3A (as shown in FIG. 3A as “Fail #1”), the memory system may detect the error using a CRC check associated with the third element 302-3. Once detected, the memory system may use the remaining data storage elements (e.g., the first element 302-1, the second element 302-2, and the fourth element 302-4 through the eighth element 302-8), as well as the first error correction element (e.g., the ninth element 302-9) to recover the lost data (e.g., the host data stored on the third element 302-3), in a similar manner as described above in connection with FIG. 2. More particularly, the memory system may derive the lost data by adding, in a bitwise fashion (e.g., using an XOR operation), host data bits stored at the remaining data storage elements (e.g., the first element 302-1, the second element 302-2, and the fourth element 302-4 through the eighth element 302-8) to the parity bits stored at the error correction element (e.g., the ninth element 302-9). In this way, the set of CRC bits at each data storage element may be used to detect errors associated with the corresponding data storage element, and the parity bits at the first data correction element may be used to correct the errors associated with a data storage element for which an error is detected.

Moreover, as indicated by reference number 309, the recovered data (e.g., the data associated with the first failed data storage element, such as the third element 302-3 in the example shown in FIG. 3A) may be replaced at the second error correction element (e.g., the tenth element 302-10). In such implementations, the first data correction element (e.g., the ninth element 302-9) may still be used to store parity bits (e.g., may still be used as a RAID parity element); however, the parity bits may be updated to reflect the new parity check payload. For example, the first error correction element (e.g., element 302-9), which originally included parity bits derived from the first element 302-1 through the eighth element 302-8, may be updated to included parity bits derived from the first element 302-1, the second element 302-2, the fourth element 302-4 through the eighth element 302-8, and the tenth element 302-10. Put another way, a set of parity bits originally included in the first error correction element (e.g., ninth element 302-9) may be derived from a payload consisting of data included in the first element 302-1 through the eighth element 302-8 (e.g., Dies #1, 2, 3, 4, 5, 6, 7, 8), and an updated set of parity bits included in the first error correction element after the replacement of the failed data storage element (e.g., the third element 302-3) with the second error correction element (e.g., the tenth element 302-10) may be derived from a payload consisting of data included in the first element 302-1, the second element 302-2, the fourth element 302-4 through the eighth 302-8, and the tenth element 302-10 (e.g., Dies #1, 2, 4, 5, 6, 7, 8, 10).

In that regard, the updated set of parity bits included at the first error correction element (e.g., the ninth element 302-9) may be used to recover any data that is lost on another data storage element, such as due to a failed die, disk, array, or the like. For example, if a second error occurs at a data storage element, such as if the sixth data storage element 302-6 fails (as shown in FIG. 3 as “Fail #2”), the memory system may detect the error using a CRC check associated with the sixth data storage element 302-6. Once detected, the memory system may use the remaining elements that now store data (e.g., the first element 302-1, the second element 302-2, the fourth element 302-4 through the eighth element 302-8, and the tenth element 302-10, which was previously used to replace the third element 302-3), as well as the first error correction element (e.g., the ninth element 302-9, which includes the updated set of parity bits) to recover the lost data (e.g., the host data stored on the failed sixth element 302-6), as indicated by reference number 310. More particularly, the memory system may derive the lost data by adding, in a bitwise fashion (e.g., using an XOR operation), host data bits stored at the remaining data storage elements (e.g., the first element 302-1, the second element 302-2, and the fourth element 302-4 through the eighth element 302-8) and the data bits stored on the second error correction element (e.g., the tenth element 302-10) to the updated parity bits stored at the first error correction element (e.g., the ninth element 302-9). In this way, by utilizing two error correction elements (e.g., the ninth element 302-10 and the tenth element 302-10 in the example shown in FIG. 3A), a memory system may be capable of performing double device data correction (e.g., recovering data for more than one failed data storage element).

In some other implementations, a memory system may associate multiple memory stripes with one another and/or may use a common set of parity bits for multiple memory stripes in order to achieve double device data correction for the memory system. For example, FIG. 3B shows an implementation in which two memory stripes are associated with one another, such as for a purpose of enabling double device data correction. In some implementations, as indicated by reference number 310, a first memory stripe 311 (labeled memory stripe A for ease of discussion), may include multiple data storage elements, such as a first element 312-1 through an eighth element 312-8 in the example shown in FIG. 3B (labeled as Die #1 through Die #8 for ease of discussion), but which may include fewer or additional elements in some other implementations. Additionally, as indicated by reference number 320, the first memory stripe 311 may include an error correction element, such as a ninth element 302-9 in the example shown in FIG. 3B (indicated using cross-hatching, and labeled Die #9 for case of discussion). Moreover, the first memory stripe 311 may be associated with another memory stripe (sometimes referred to as a twin memory stripe), such as a second memory stripe 315 shown in FIG. 3B (labeled memory stripe B for case of discussion). In this regard, the implementation shown in FIG. 3B may sometimes be referred to as a “twinning approach.” In a similar manner as described above in connection with the first memory stripe 311, and as indicated by reference number 310, the second memory stripe 315 may be associated with multiple data storage elements, such as a first element 316-1 through an eighth element 316-8 in the example shown in FIG. 3B (labeled as Die #1 through Die #8 for case of discussion), but which may include fewer or additional elements in some other examples. Additionally, as indicated by reference number 318, the second memory stripe 315 may be associated with an error correction element, such as a ninth element 316-9 in the example shown in FIG. 3B (indicated using cross-hatching and labeled Die #9 for case of discussion). In some examples, the data storage elements (e.g., Dies #1 through Dies #8) of the memory stripes 311, 315 may be used to store host data, and the error correction elements (e.g., Dies #9) may be used to stored parity bits used for error correction of the host data.

In this implementation, the data storage elements of at least one memory stripe may be associated with a common parity check payload, and a corresponding error correction element of the at least one memory stripe may be used to store parity bits associated with the common parity check payload. For example, in the example shown in FIG. 3B, the ninth element 312-9 of the second memory stripe 315 may be used to store common parity bits associated with the common parity check payload (e.g., the payload of both stripe A and stripe B, as indicated by reference number 318), and thus may, in some implementations, be referred to as a RAID parity die. As described above in connection with FIG. 2, the parity bits may be derived from the parity check payload, such as by performing an XOR operation associated with the data bits stored on the data storage elements (e.g., Die #1 through Die #8 of stripe A and stripe B). In this way, the parity bits of the ninth element 312-9 of the second memory stripe 315 may be used to perform read error recovery procedures on either the first memory stripe 311 or the second memory stripe 315. This may enable double device data correction on a given memory strip (e.g., the first memory stripe 311 in the example shown in FIG. 3B), such by, for example, using parity bits associated with the error correction element (e.g., the ninth element 312-9) of the first memory stripe 311 for correcting a first error, and/or by using parity bits associated with the error correction element (e.g., the ninth element 316-9) of the second memory stripe 315 for correcting a second error.

More particularly, in a similar manner as described above in connection with FIGS. 2 and 3A, each data storage element (e.g., the first elements 312-1, 316-1 through the eighth elements 312-8, 316-8) may include a respective set of CRC bits, such as a set of CRC bits stored in space of the data storage element that is not used for storing host data. In this way, if a first error occurs at a data storage element, such as if the third element 312-3 of the first memory stripe 311 fails (shown in FIG. 3 as “Fail #1”), the memory system may detect the error using a CRC check associated with the third element 312-3. Once detected, the memory system may use the remaining data storage elements of the first memory stripe 311 (e.g., the first element 312-1, the second element 312-2, and the fourth element 312-4 through the eighth element 312-8), as well as the error correction element of the first memory stripe 311 (e.g., the ninth element 312-9) to recover the lost data, in a similar manner as described above in connection with FIG. 2. More particularly, the memory system may derive the lost data by adding, in a bitwise fashion (e.g., using an XOR operation), host data bits stored at the remaining data storage elements of the first memory stripe 311 (e.g., the first element 312-1, the second element 312-2, and the fourth element 312-4 through the eighth element 312-8) to the parity bits stored at the error correction element of the first memory stripe 311 (e.g., the ninth element 312-9). In this way, the set of CRC bits at each data storage element of the first memory stripe 311 may be used to detect errors associated with the corresponding data storage element, and the parity bits at the first data correction element of the first memory stripe 311 may be used to correct the errors associated with a data storage element for which an error is detected.

Moreover, as indicated by reference number 322, the recovered data (e.g., the data associated with the first failed element, such as the third element 312-3 in the example shown in FIG. 3B) may be replaced at the error correction element associated with the first memory stripe 311 (e.g., the ninth element 312-9). For example, if a cluster of errors are detected multiple times on a given data storage element (e.g., the third element 312-3 in the example shown in FIG. 3B), the memory system may replace the failed data storage element with the error correction element (e.g., the ninth element 312-9). In such implementations, to preserve a capability to correct a second error on the first memory stripe 311, notwithstanding that the error correction element is now being used to store data (e.g., notwithstanding that the error correction element is used a replacement for a failed data storage element), the first memory stripe 311 may be associated with the second memory stripe 315, such that a common parity stored at the error correction element of the second memory stripe 315 (e.g., the ninth element 316-9) may be used to correct future errors at the first memory stripe 311.

More particularly, in such implementations, the data correction element of the second memory stripe 315 (e.g., the ninth element 316-9) may be used to store parity bits associated with both the first memory stripe 311 and the second memory stripe 315. In that regard, the set of common parity bits included at the error correction element (e.g., the ninth element 316-9) of the second memory stripe 315 may be used to recover any data that is lost on another data storage element of the first memory stripe 311, such as due to a failed die, disk, array, or the like. For example, if a second error occurs at a data storage element of the first memory stripe 311, such as if the sixth data storage element 312-6 fails (as shown in FIG. 3B as “Fail #2”), the memory system may detect the error using a CRC check associated with the sixth data storage element 312-6. Once detected, the memory system may use the elements of the first memory stripe 311 that are storing data (e.g., the first element 312-1, the second element 312-2, and the fourth element 312-4 through the ninth element 312-9), the elements of the second memory stripe 315 that are storing data (e.g., the first element 316-1 through the eighth element 316-8), and the error correction element of the second memory stripe 315 (e.g., the ninth element 316-9, which includes the set of common parity bits) to recover the lost data (e.g., the host data stored on the failed sixth element 312-6 of the first memory stripe 311), as indicated by reference number 324. More particularly, the memory system may derive the lost data by adding, in a bitwise fashion (e.g., using an XOR operation), host data bits stored at the remaining data storage elements (e.g., the first element 312-1, the second element 312-2, and the fourth element 312-4 through the ninth element 312-9 of the first memory stripe 311 and the first element 316-1 through the eighth element 316-8 of the second memory stripe 315) to the common parity bits stored at the error correction element of the second memory stripe 315 (e.g., the ninth element 316-9 of the second memory stripe 315). In this way, by utilizing two associated memory stripes (e.g., the first memory stripe 311 and the second memory stripe 315) that are associated with a common parity element, a memory system may be capable of performing double device data correction (e.g., recovering data for more than one data storage element of the first memory stripe 311).

In some implementations, utilizing the operations described above in connection with FIG. 3B may enable a reduction of die-overhead as compared to the operations described above in connection with FIG. 3A, because only a single error correction element (e.g., a single die) is associated with each memory stripe. For example, for implementations in which a memory stripe is associated with eight data storage elements, the operations described above in connection with FIG. 3A may result in a die overhead of 25% (e.g., for every eight data storage elements, two data correction elements may be needed), while the operations described above in connection with FIG. 3B may result in a die overhead of 12.5% (e.g., for every eight data storage elements, only one data correction element may be needed). However, implementing the operations described above in connection with FIG. 3B may result in increased power, computing, and similar resource consumption as compared to the operations described above in connection with FIG. 3A, because data from only multiple memory stripes may need to be accessed and/or processed when performing read or write procedures associated with twin memory stripes.

For example, after replacing a failed data storage element of the first memory stripe 311 with the error correction element (as described above in connection with reference number 322), the memory system may use both memory stripes 311, 315 cooperatively to implement error recovery procedures for the memory stripes (sometimes referred to as chipkill protection for the memory stripes). For example, when performing read operations on the first memory stripe 311 prior to replacing a failed data storage element of the first memory stripe 311 with the error correction element, the memory system may perform the read operations operation normally (e.g., without reference to the second memory stripe 315), such as would be performed in connection with the operations described above in connection with FIG. 2. However, after replacing a failed data storage element of the first memory stripe 311 with the error correction element, the memory system may need to read codewords associated with both the first memory stripe 311 and the second memory stripe 315 and/or may need to access the common parity bits stored at the second memory stripe 315 in order to recover the lost data.

Similarly, when performing write operations on the first memory stripe 311 prior to replacing a failed data storage element of the first memory stripe 311 with the error correction element, the memory system may perform the write operation normally (e.g., without reference to the second memory stripe 315), such as would be performed in connection with the operations described above in connection with FIG. 2. However, after replacing a failed data storage element of the first memory stripe 311 with the error correction element, to perform write operations the memory system may read the data associated with the second memory stripe 315, such as for a purpose of updating the common parity associated the error correction element of the second memory stripe 315. For example, the memory system may update the common parity by adding, in a bitwise fashion (e.g., by performing an XOR operation), the delta between new data being written (e.g., a written data pattern) and the old data (e.g., a stored data pattern) to the common parity. Because, in such implementations, the memory system may need to only update the parity (e.g., because, in such implementations, the memory system may not need to update the data stored on the data storage elements of the second memory stripe 315), in some implementations, the memory system may only access the parity bits, and not data bits, associated with the second memory stripe 315, such as in implementations in which an independent channel is associated with the error correction element (e.g., the parity die) and thus the error correction element of the second memory stripe 315 may be accessed without accessing the data storage elements of the second memory stripe 315.

As indicated above, FIGS. 3A-3B are provided as an example. Other examples may differ from what is described with regard to FIGS. 3A-3B.

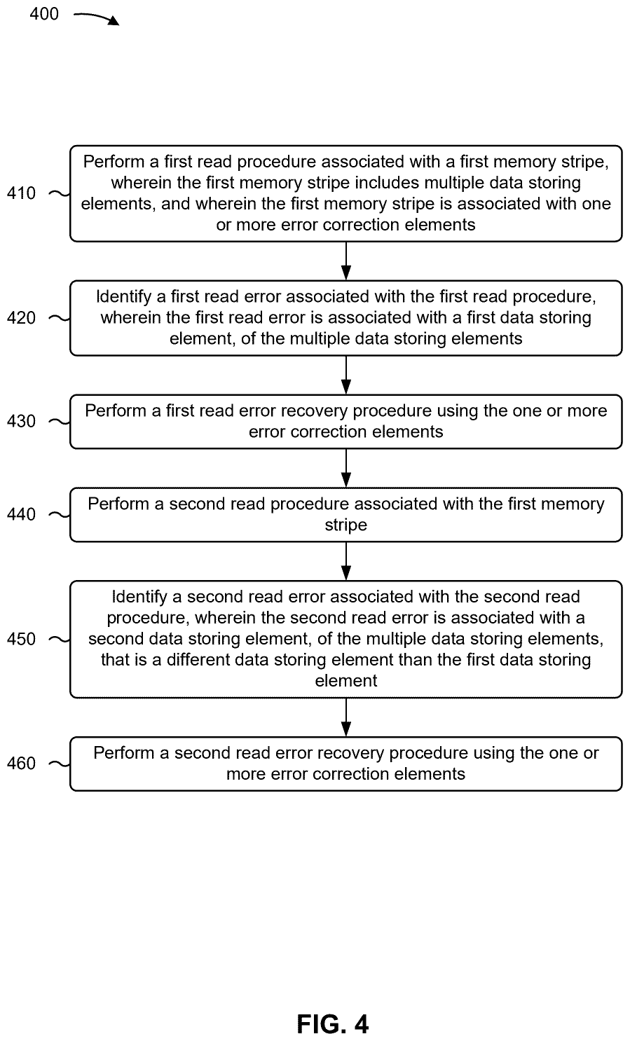

FIG. 4 is a flowchart of an example method 400 associated with double device data correction for RAID-based systems. In some implementations, a memory system (e.g., the memory system 110) may perform or may be configured to perform the method 400. Additionally, or alternatively, one or more components of the memory system (e.g., memory system controller 115, one or more memory devices 120, and/or one or more local controllers 125) may perform or may be configured to perform the method 400. Thus, means for performing the method 400 may include the memory system and/or one or more components of the memory system. Additionally, or alternatively, a non-transitory computer-readable medium may store one or more instructions that, when executed by the memory system, cause the memory system to perform the method 400.

As shown in FIG. 4, the method 400 may include performing a first read procedure associated with a first memory stripe, wherein the first memory stripe includes multiple data storage elements, and wherein the first memory stripe is associated with one or more error correction elements (block 410). As further shown in FIG. 4, the method 400 may include identifying a first read error associated with the first read procedure, wherein the first read error is associated with a first data storage element, of the multiple data storage elements (block 420). As further shown in FIG. 4, the method 400 may include performing a first read error recovery procedure using the one or more error correction elements (block 430). As further shown in FIG. 4, the method 400 may include performing a second read procedure associated with the first memory stripe (block 440). As further shown in FIG. 4, the method 400 may include identifying a second read error associated with the second read procedure, wherein the second read error is associated with a second data storage element, of the multiple data storage elements, that is a different data storage element than the first data storage element (block 450). As further shown in FIG. 4, the method 400 may include performing a second read error recovery procedure using the one or more error correction elements (block 460).

The method 400 may include additional aspects, such as any single aspect or any combination of aspects described below and/or described in connection with one or more other methods or operations described elsewhere herein.

In a first aspect, the first read error recovery procedure and the second read error recovery procedure are associated with a redundant-array-of-independent-disks read error recovery procedure.

In a second aspect, alone or in combination with the first aspect, performing the first read error recovery procedure includes using a first payload associated with a first error correction element, of the one or more error correction elements, and performing the second read error recovery procedure includes using a second payload associated with the first error correction element.

In a third aspect, alone or in combination with one or more of the first and second aspects, the method 400 includes writing data associated with the first data storage element to a second error correction element, of the one or more error correction elements, based on identifying the first read error, and updating a payload associated with the first error correction element from the first payload to the second payload based on writing the data associated with the first data storage element to the second error correction element.

In a fourth aspect, alone or in combination with one or more of the first through third aspects, performing the first read error recovery procedure includes using a first payload associated with a first error correction element, of the one or more error correction elements, and performing the second read error recovery procedure includes using a second payload associated with a second error correction element, of the one or more error correction elements.

In a fifth aspect, alone or in combination with one or more of the first through fourth aspects, the method 400 includes writing data associated with the first data storage element to the first error correction element based on identifying the first read error.

In a sixth aspect, alone or in combination with one or more of the first through fifth aspects, the first memory stripe includes the first error correction element, and a second memory stripe, different than the first memory stripe, includes the second error correction element.

In a seventh aspect, alone or in combination with one or more of the first through sixth aspects, the second payload includes a sum of a first parity data associated with the first memory stripe and a second parity data associated with the second memory stripe.

In an eighth aspect, alone or in combination with one or more of the first through seventh aspects, the method 400 includes performing a third read procedure associated with the second memory stripe, identifying a third read error associated with the third read procedure, and performing a third read error recovery procedure using the second payload.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

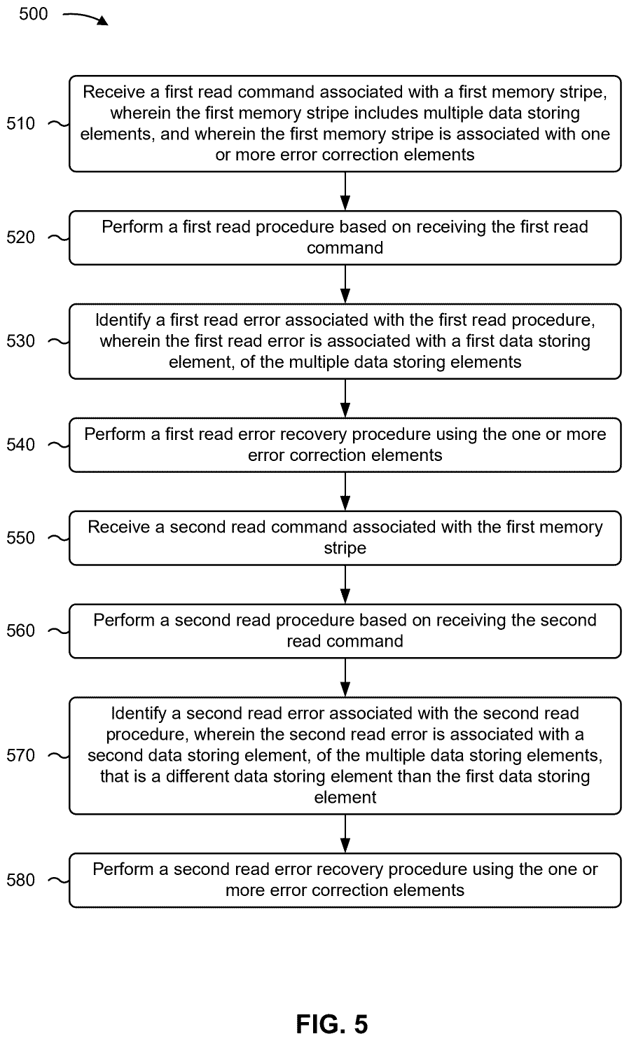

FIG. 5 is a flowchart of an example method 500 associated with double device data correction for RAID-based systems. In some implementations, a memory system (e.g., the memory system 110) may perform or may be configured to perform the method 500. Additionally, or alternatively, one or more components of the memory system (e.g., memory system controller 115, one or more memory devices 120, and/or one or more local controllers 125) may perform or may be configured to perform the method 500. Thus, means for performing the method 500 may include the memory system and/or one or more components of the memory system. Additionally, or alternatively, a non-transitory computer-readable medium may store one or more instructions that, when executed by the memory system, cause the memory system to perform the method 500.

As shown in FIG. 5, the method 500 may include receiving a first read command associated with a first memory stripe, wherein the first memory stripe includes multiple data storage elements, and wherein the first memory stripe is associated with one or more error correction elements (block 510). As further shown in FIG. 5, the method 500 may include performing a first read procedure based on receiving the first read command (block 520). As further shown in FIG. 5, the method 500 may include identifying a first read error associated with the first read procedure, wherein the first read error is associated with a first data storage element, of the multiple data storage elements (block 530). As further shown in FIG. 5, the method 500 may include performing a first read error recovery procedure using the one or more error correction elements (block 540). As further shown in FIG. 5, the method 500 may include receiving a second read command associated with the first memory stripe (block 550). As further shown in FIG. 5, the method 500 may include performing a second read procedure based on receiving the second read command (block 560). As further shown in FIG. 5, the method 500 may include identifying a second read error associated with the second read procedure, wherein the second read error is associated with a second data storage element, of the multiple data storage elements, that is a different data storage element than the first data storage element (block 570). As further shown in FIG. 5, the method 500 may include performing a second read error recovery procedure using the one or more error correction elements (block 580).

The method 500 may include additional aspects, such as any single aspect or any combination of aspects described below and/or described in connection with one or more other methods or operations described elsewhere herein.

In a first aspect, the first read error recovery procedure and the second read error recovery procedure are associated with a redundant-array-of-independent-disks read error recovery procedure.

In a second aspect, alone or in combination with the first aspect, performing the first read error recovery procedure comprises using a first payload associated with a first error correction element, of the one or more error correction elements, and performing the second read error recovery procedure comprises using a second payload associated with the first error correction element.

In a third aspect, alone or in combination with one or more of the first and second aspects, the method 500 includes writing, by the memory system, data associated with the first data storage element to a second error correction element, of the one or more error correction elements, based on identifying the first read error, and updating, by the memory system, a payload associated with the first error correction element from the first payload to the second payload based on writing the data associated with the first data storage element to the second error correction element.

In a fourth aspect, alone or in combination with one or more of the first through third aspects, performing the first read error recovery procedure comprises using a first payload associated with a first error correction element, of the one or more error correction elements, and performing the second read error recovery procedure comprises using a second payload associated with a second error correction element, of the one or more error correction elements.

In a fifth aspect, alone or in combination with one or more of the first through fourth aspects, the method 500 includes writing, by the memory system, data associated with the first data storage element to the first error correction element based on identifying the first read error.

In a sixth aspect, alone or in combination with one or more of the first through fifth aspects, the first memory stripe includes the first error correction element, and a second memory stripe, different than the first memory stripe, includes the second error correction element.

In a seventh aspect, alone or in combination with one or more of the first through sixth aspects, the second payload includes a sum of a first parity data associated with the first memory stripe and a second parity data associated with the second memory stripe.

In an eighth aspect, alone or in combination with one or more of the first through seventh aspects, the method 500 includes receiving, by the memory system, a third read command associated with a second memory stripe, performing, by the memory system, a third read procedure based on receiving the third read command, identifying, by the memory system, a third read error associated with the third read procedure, and performing, by the memory system, a third read error recovery procedure using the second payload.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

In some implementations, a memory system includes one or more components configured to: perform a first read procedure associated with a first memory stripe, wherein the first memory stripe includes multiple data storage elements, and wherein the first memory stripe is associated with one or more error correction elements; identify a first read error associated with the first read procedure, wherein the first read error is associated with a first data storage element, of the multiple data storage elements; perform a first read error recovery procedure using the one or more error correction elements; perform a second read procedure associated with the first memory stripe; identify a second read error associated with the second read procedure, wherein the second read error is associated with a second data storage element, of the multiple data storage elements, that is a different data storage element than the first data storage element; and perform a second read error recovery procedure using the one or more error correction elements.

In some implementations, a method includes receiving, by a memory system, a first read command associated with a first memory stripe, wherein the first memory stripe includes multiple data storage elements, and wherein the first memory stripe is associated with one or more error correction elements; performing, by the memory system, a first read procedure based on receiving the first read command; identifying, by the memory system, a first read error associated with the first read procedure, wherein the first read error is associated with a first data storage element, of the multiple data storage elements; performing, by the memory system, a first read error recovery procedure using the one or more error correction elements; receiving, by the memory system, a second read command associated with the first memory stripe; performing, by the memory system, a second read procedure based on receiving the second read command; identifying, by the memory system, a second read error associated with the second read procedure, wherein the second read error is associated with a second data storage element, of the multiple data storage elements, that is a different data storage element than the first data storage element; and performing, by the memory system, a second read error recovery procedure using the one or more error correction elements.

In some implementations, a non-transitory computer-readable medium storing a set of instructions includes one or more instructions that, when executed by one or more processors of a memory system, cause the memory system to: perform a first read procedure associated with a first memory stripe, wherein the first memory stripe includes multiple data storage elements, and wherein the first memory stripe is associated with one or more error correction elements; identify a first read error associated with the first read procedure, wherein the first read error is associated with a first data storage element, of the multiple data storage elements; perform a first read error recovery procedure using the one or more error correction elements; perform a second read procedure associated with the first memory stripe; identify a second read error associated with the second read procedure, wherein the second read error is associated with a second data storage element, of the multiple data storage elements, that is a different data storage element than the first data storage element; and perform a second read error recovery procedure using the one or more error correction elements.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory system, comprising:
one or more components configured to:
perform a first read procedure associated with a first memory stripe,
wherein the first memory stripe includes multiple data storage elements, and
wherein the first memory stripe is associated with one or more error correction elements;
identify a first read error associated with the first read procedure,
wherein the first read error is associated with a first data storage element, of the multiple data storage elements;
perform a first read error recovery procedure using the one or more error correction elements;
perform a second read procedure associated with the first memory stripe;
identify a second read error associated with the second read procedure,
wherein the second read error is associated with a second data storage element, of the multiple data storage elements, that is a different data storage element than the first data storage element; and
perform a second read error recovery procedure using the one or more error correction elements.

2. The memory system of claim 1, wherein the first read error recovery procedure and the second read error recovery procedure are associated with a redundant-array-of-independent-disks read error recovery procedure.

3. The memory system of claim 1, wherein the one or more components, to perform the first read error recovery procedure, are configured to use a first payload associated with a first error correction element, of the one or more error correction elements, and
wherein the one or more components, to perform the second read error recovery procedure, are configured to use a second payload associated with the first error correction element.

4. The memory system of claim 3, wherein the one or more components are further configured to:
write data associated with the first data storage element to a second error correction element, of the one or more error correction elements, based on identifying the first read error; and
update a payload associated with the first error correction element from the first payload to the second payload based on writing the data associated with the first data storage element to the second error correction element.

5. The memory system of claim 1, wherein the one or more components, to perform the first read error recovery procedure, are configured to use a first payload associated with a first error correction element, of the one or more error correction elements, and
wherein the one or more components, to perform the second read error recovery procedure, are configured to use a second payload associated with a second error correction element, of the one or more error correction elements.

6. The memory system of claim 5, wherein the one or more components are further configured to write data associated with the first data storage element to the first error correction element based on identifying the first read error.

7. The memory system of claim 5, wherein the first memory stripe includes the first error correction element, and
wherein a second memory stripe, different than the first memory stripe, includes the second error correction element.

8. The memory system of claim 7, wherein the second payload includes a sum of a first parity data associated with the first memory stripe and a second parity data associated with the second memory stripe.

9. The memory system of claim 7, wherein the one or more components are further configured to:
perform a third read procedure associated with the second memory stripe;
identify a third read error associated with the third read procedure; and
perform a third read error recovery procedure using the second payload.

10. A method, comprising:
receiving, by a memory system, a first read command associated with a first memory stripe,
wherein the first memory stripe includes multiple data storage elements, and
wherein the first memory stripe is associated with one or more error correction elements;
performing, by the memory system, a first read procedure based on receiving the first read command;
identifying, by the memory system, a first read error associated with the first read procedure,
wherein the first read error is associated with a first data storage element, of the multiple data storage elements;
performing, by the memory system, a first read error recovery procedure using the one or more error correction elements;
receiving, by the memory system, a second read command associated with the first memory stripe;
performing, by the memory system, a second read procedure based on receiving the second read command;
identifying, by the memory system, a second read error associated with the second read procedure,
wherein the second read error is associated with a second data storage element, of the multiple data storage elements, that is a different data storage element than the first data storage element; and
performing, by the memory system, a second read error recovery procedure using the one or more error correction elements.

11. The method of claim 10, wherein the first read error recovery procedure and the second read error recovery procedure are associated with a redundant-array-of-independent-disks read error recovery procedure.

12. The method of claim 10, wherein performing the first read error recovery procedure comprises using a first payload associated with a first error correction element, of the one or more error correction elements, and
wherein performing the second read error recovery procedure comprises using a second payload associated with the first error correction element.

13. The method of claim 12, further comprising:
writing, by the memory system, data associated with the first data storage element to a second error correction element, of the one or more error correction elements, based on identifying the first read error; and
updating, by the memory system, a payload associated with the first error correction element from the first payload to the second payload based on writing the data associated with the first data storage element to the second error correction element.

14. The method of claim 10, wherein performing the first read error recovery procedure comprises using a first payload associated with a first error correction element, of the one or more error correction elements, and
wherein performing the second read error recovery procedure comprises using a second payload associated with a second error correction element, of the one or more error correction elements.

15. The method of claim 14, further comprising writing, by the memory system, data associated with the first data storage element to the first error correction element based on identifying the first read error.

16. The method of claim 14, wherein the first memory stripe includes the first error correction element, and
wherein a second memory stripe, different than the first memory stripe, includes the second error correction element.

17. The method of claim 16, wherein the second payload includes a sum of a first parity data associated with the first memory stripe and a second parity data associated with the second memory stripe.

18. The method of claim 16, further comprising:
receiving, by the memory system, a third read command associated with the second memory stripe;
performing, by the memory system, a third read procedure based on receiving the third read command;
identifying, by the memory system, a third read error associated with the third read procedure; and
performing, by the memory system, a third read error recovery procedure using the second payload.

19. A non-transitory computer-readable medium storing a set of instructions, the set of instructions comprising:
one or more instructions that, when executed by one or more processors of a memory system, cause the memory system to:
perform a first read procedure associated with a first memory stripe,
wherein the first memory stripe includes multiple data storage elements, and
wherein the first memory stripe is associated with one or more error correction elements;
identify a first read error associated with the first read procedure,
wherein the first read error is associated with a first data storage element, of the multiple data storage elements;
perform a first read error recovery procedure using the one or more error correction elements;
perform a second read procedure associated with the first memory stripe;
identify a second read error associated with the second read procedure,
wherein the second read error is associated with a second data storage element, of the multiple data storage elements, that is a different data storage element than the first data storage element; and
perform a second read error recovery procedure using the one or more error correction elements.

20. The non-transitory computer-readable medium of claim 19, wherein the first read error recovery procedure and the second read error recovery procedure are associated with a locked-redundant-array-of-independent-disks read error recovery procedure.
